(19) United States
(12) Patent Application Publication
(10) Pub. No.: US 2026/0044651 A1
(43) Pub. Date: Feb. 12, 2026

(54) SYSTEMS AND METHODS FOR PREDICTING FUNCTIONS BASED ON MULTIMODAL DATA OBJECTS

(71) Applicant: The University of North Carolina at Charlotte, Charlotte, NC (US)

(72) Inventors: George BANKS, Waxhaw, NC (US); Wenwen DOU, Charlotte, NC (US); Scott TONIDANDEL, Clemmons, NC (US)

(21) Appl. No.: 19/296,520

(22) Filed: Aug. 11, 2025

Related U.S. Application Data
(60) Provisional application No. 63/682,093, filed on Aug. 12, 2024.

(51) Int. Cl. G06F 30/27

(52) U.S. Cl. CPC G06F 30/27

(57) ABSTRACT

Systems, methods, and non-transitory computer readable mediums are provided herein for receiving one or more multimodal data objects associated with a subject entity and one or more interactions with an electronic device. The subject entity can include a software module, a digital asset, a system component, an individual, or the like. A multimodal data object is derived from analysis of at least video, audio, and textual data. A predictive function data object is generated based on multimodal data objects by a predictive function model. A predictive function data object is configured to predict how subject entity expressions impact one or more additional entities. One or more actions are performed based on the predictive function data object. An action performed can include reconfiguring a composition of one or more structural data objects, generating electronic communications, and the like. Electronic communications are provided in real-time and/or subsequent to an interactive session.

### CROSS REFERENCE TO RELATED APPLICATION

This application claims priority to U.S. Provisional Application 63/682,093, filed Aug. 12, 2024, the entire contents of which are hereby incorporated by reference.

### SUPPORT STATEMENT

This invention was made with government support under AWD-IPF2024-0573 awarded by the National Science Foundation. This invention was made with support under AWD-IPF2023-1064 awarded by the Department of the Army. The government has certain rights in the invention.

### TECHNOLOGICAL FIELD

The embodiments disclosed herein generally relate to predicting functions based on multimodal data objects.

### BACKGROUND

In modern organizational environments, digital interactions span a wide range of technologies, including video conferencing, instant messaging, email, voice communication, and collaborative platforms. Current systems lack the technical capability to integrate and interpret data from various systems in a cohesive and predictive manner.

Traditional evaluation tools are often limited to static metrics or manual assessments, which fail to capture the nuanced and dynamic nature of digital interactions. Moreover, existing systems typically operate in silos, analyzing data from a single modality or relying on predefined templates that do not adapt to evolving behavioral patterns.

Such systems also lack synthesis of heterogeneous data types that can be gleaned from digital interactions, such as audio tone, facial expressions, textual sentiment, and interaction patterns. Accordingly, any actionable feedback provided from such systems may fall short in its predictions and recommendations.

With the rise of online work environments and virtual collaboration, the amount of digital data available for consumption has also increased. However, existing systems and methods have failed to leverage the vast amount of digital data, and are also vulnerable to subjective bias. Moreover, existing systems are not adapted to multimodal contexts, such as but not limited to data from online contexts, virtual settings, email, chat, and the like.

### BRIEF SUMMARY

Systems, and methods for predicting functions based on multimodal data objects are therefore provided. The disclosed system addresses technical challenges in synthesizing heterogenous data types such as audio tone, facial expressions, textual sentiment, and interaction patterns into a unified predictive model capable of generating actionable insights.

Example embodiments disclosed herein ingest and process multimodal data associated with user interactions with an electronic device, and apply predictive modeling techniques to dynamically update models using event markers and annotated training data, to derive predictive function data objects. By leveraging advanced machine learning models, including large language models, the system generates predictive function data objects that forecast potential or future operational states, configurations, or behaviors of a subject entity within an electronic environment. These predictive outputs may be used to inform automated system responses, optimize resource allocation, or reconfigure digital components based on anticipated functional trajectories.

In this regard, a functional trajectory refers to the evolving sequence of computational states, transformations, and inferred outcomes that digital data undergoes as it is processed within an electronic system. In the disclosed system, multimodal digital data, such as audio signals, image frames, textual content, electronic communications, and the like, is ingested and mapped to a structured representation that reflects its operational relevance. The model generates a predictive function data object that encapsulates the anticipated predicted function, such as a future state, configuration, or the like, of the subject entity (e.g., a software module, digital asset, or system component).

In some embodiments, a computer-implemented method, system, computer program product, and/or apparatus is provided. In some embodiments, the computer-implemented method, system, computer program product, and/or apparatus is configured to receive one or more multimodal data objects associated with a subject entity and one or more interactions with an electronic device, generate, by applying the one or more multimodal data objects to a predictive function model, a predictive function data object associated with at least the subject entity, and perform one or more actions based on the predictive function data object.

In some embodiments, the computer-implemented method, system, computer program product, and/or apparatus are configured to update the predictive function model by applying a sequence of multimodal data objects having respective one or more event markers.

In some embodiments, the one or more multimodal data objects are further associated with one or more additional entities, and wherein the predictive function data object is further associated with the one or more additional entities.

In some embodiments, the predictive function data object is associated with inter-related functions of a plurality of entities.

In some embodiments, the one or more multimodal data objects are derived from one or more of electronic mail messages, short message service (SMS) texts, video data, rich communication services (RCS), electronic images, instant message data, chat data, virtual meeting interaction data, audio data, or online communication vehicles.

In some embodiments, the computer-implemented method, system, computer program product, and/or apparatus are configured to receive one or more annotated multimodal data objects, generate the predictive function model based on the one or more annotated multimodal data objects, and update the predictive function model based on one or more training parameters.

In some embodiments, the predictive function data object is associated with one or more of a charismatic leadership feature, an ethical leadership feature, a transformational leadership feature, a shared leadership feature, a transactional leadership feature, an authentic leadership feature, a destructive leadership feature, an effective leadership feature, or a supportive followership feature.

In some embodiments, the predictive function model comprises a large language model.

In some embodiments, the computer-implemented method, system, computer program product, and/or apparatus are configured to generate one or more subject entity performance interface components and cause rendering of the one or more subject entity performance interface components via a display device of the electronic device associated with the subject entity.

In some embodiments, the computer-implemented method, system, computer program product, and/or apparatus are configured to generate an electronic communication indicating at least one of one or more subject entity behavior improvement features, or a team composition feature.

In some embodiments, the computer-implemented method, system, computer program product, and/or apparatus are configured to reconfigure a composition of one or more structural data objects.

In some embodiments, the computer-implemented method, system, computer program product, and/or apparatus are configured to cause rendering of the electronic communication via a display device of the electronic device associated with the subject entity in real time during a virtual meeting.

In some embodiments, the computer-implemented method, system, computer program product, and/or apparatus are configured to receive one or more additional multimodal data objects associated with a subject entity and one or more interactions with an electronic device, generate, by applying the one or more additional multimodal data objects to the predictive function model, a subject entity profile associated with at least the subject entity, generate, based on the subject entity profile, an electronic communication configured for display via a display device, transmit the electronic communication to the electronic device associated with the subject entity.

### BRIEF DESCRIPTION OF THE DRAWINGS

FIG. 1 provides an example overview of a system that can be used to practice embodiments of the present disclosure.

FIG. 2 provides an example predictive data analysis computing entity in accordance with some embodiments discussed herein.

FIG. 3 provides an example external computing entity in accordance with some embodiments discussed herein.

FIG. 4 provides an example data flow in accordance with some embodiments discussed herein.

FIGS. 5A-5E are example subject entity performance interface components in accordance with some embodiments discussed herein.

FIG. 6 provides an example method in accordance with some embodiments discussed herein.

### DETAILED DESCRIPTION

Various embodiments of the present disclosure are described more fully hereinafter with reference to the accompanying drawings, in which some, but not all embodiments of the present disclosure are shown. Indeed, the present disclosure may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Terms such as “computing,” “determining,” “generating,” and/or similar words are used herein interchangeably to refer to the creation, modification, or identification of data. Further, “based on,” “based at least in part on,” “based at least on,” “based upon,” and/or similar words are used herein interchangeably in an open-ended manner such that they do not necessarily indicate being based only on or based solely on the referenced element or elements unless so indicated. Like numbers refer to like elements throughout. Moreover, while certain embodiments of the present disclosure are described with reference to predictive data analysis, one of ordinary skill in the art will recognize that the disclosed concepts can be used to perform other types of data analysis.

Example embodiments of the systems and methods provided herein utilize a predictive function model trained on multimodal data objects associated with a subject entity and one or more interactions with an electronic device. In some embodiments, the multimodal data objects are further associated with one or more additional entities. In this regard, for example, a subject entity may be an active speaker in an interactive session, such as a virtual meeting. Continuing the above example, one or more additional entities may be one or more stakeholders observing and/or interacting with the active speaker in a virtual context. Additional entity reactions and responses to the subject entity are captured by one or more multimodal data objects. The predictive function model, as executed by a predictive data analysis entity, is configured to analyze a plurality of signals (e.g., video, audio and/or textual data indicative of facial expressions, body language, transcribed speech, tone of voice, pitch, semantics, syntax, texts, emails, and/or the like). The multimodal data object can further include data from virtual meeting video data, virtual meeting audio data, electronic mail messages, short message service (SMS) texts, virtual meeting chat messages, transcribed speech, rich communication services (RCS), electronic image data, instant message data, online communication vehicles, and/or the like.

Example embodiments may, in response to inputting a multimodal data object to a trained predictive function model to generate a predictive function data object, perform an action associated based on the predictive function data object. Accordingly, example embodiments may perform an action including reconfiguring a composition of one or more structural data objects, such as when a hierarchical data structure is represented in an electronic format. An action produced by example embodiments may include reconfiguring the hierarchy, removing specific elements, relocating elements to different branches, modifying node relationships, and/or similar structural adjustments. In this regard, example embodiments may be used to reorganize digital resources, optimize data architectures, or restructure system configurations based on predictive outputs. In this regard, example embodiments may be used to reconfigure, or reorganize, clusters of resources, such as but not limited to human resources represented in an electronic structural data object having a hierarchical format.

In some embodiments, the predictive function model is configured to generate electronic communications configured to improve leadership qualities, leader performance, team performance, and team composition in real-time in an interactive session (e.g., online contexts, virtual meetings, and/or the like) by providing immediate, short bursts of subject entity behavior improvement features (e.g., feedback, advice, and/or instructions regarding speaking habits, leadership styles, context-aware suggestions, and/or the like) directly via a display of a computing device associated with the subject entity, such as an external computing entity. In some embodiments, subject entity behavior improvement features may be configured to be provided to a subject entity subsequent to a virtual meeting via one or more subject entity performance interface components. In some embodiments, the electronic communications are configured to provide team composition features (e.g., feedback, advice, and/or instructions regarding inter-related functions of a plurality of entities) directly via a display of a computing device associated with the subject entity and displays of computing devices associated with the one or more additional entities.

In some embodiments, a subject entity profile is generated over time. As a subject entity partakes in more virtual interactions with others, additional multimodal data objects, additional predictive function data objects, and additional subject entity behavior improvement features are generated. These form an increasing dataset associated with the subject entity that is configured to enable the predictive function model to be updated, providing a holistic data representation of the subject entity's actions, further improving the quality of generation of subsequent predictive function data objects, such as those comprising behavior improvement features, and/or the like. By providing sophisticated analytical metrics associated with a subject entity profile via one or more subject entity performance interface components, trends and changes to behaviors, habits, leadership styles, and real-world impacts of individuals' words and actions on stakeholders can be captured and optionally visualized.

In some embodiments, the predictive function model is configured to generate a predictive function data object based on one or more multimodal data objects. In some embodiments, the predictive function data object is associated with one or more predictive functions. In this regard, for example, a predictive function data object may comprise one or more of a charismatic leadership feature, an ethical leadership feature, a transformational leadership feature, a shared leadership feature, a transactional leadership feature, an authentic leadership feature, a destructive leadership feature, an effective leadership feature, or a supportive followership feature.

Charismatic leadership may be signaled through verbal behaviors such as metaphors, similes, anecdotes, and rhetorical questions. Ethical leadership may be signaled through behavior by the leader targeted at stakeholders comprising the enactment of prosocial values combined with expressions of moral emotions, and may be marked by verbal behaviors regarding morals, rules, fairness, and positive communication. Transformational leadership may be signaled through developmental and prosocial behaviors tailored for each unique stakeholder and is marked by verbal behaviors such as sharing life lessons and speaking words of affirmation. Destructive leadership may be signaled through behavior that is hostile and destructive, and may be marked by threatening, abusive, narcissistic, or Machiavellian expressions, as well as lack of professional decorum and use of favoritism.

### I. Computer Program Products, Methods, and Computing Entities

Embodiments of the present disclosure may be implemented in various ways, including as computer program products that comprise articles of manufacture. Such computer program products may include one or more software components including, for example, software objects, methods, data structures, or the like. A software component may be coded in any of a variety of programming languages. An illustrative programming language may be a lower-level programming language such as an assembly language associated with a particular hardware framework and/or operating system platform. A software component comprising assembly language instructions may require conversion into executable machine code by an assembler prior to execution by the hardware framework and/or platform. Another example programming language may be a higher-level programming language that may be portable across multiple frameworks. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query, or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as in a particular directory, folder, or library. Software components may be static (e.g., pre-established or fixed) or dynamic (e.g., created or modified at the time of execution).

A computer program product may include non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD)), solid state card (SSC), solid state module (SSM), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatuses, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatuses, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some example embodiments, retrieval, loading, and/or execution may be performed in parallel such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

### II. Example System Framework

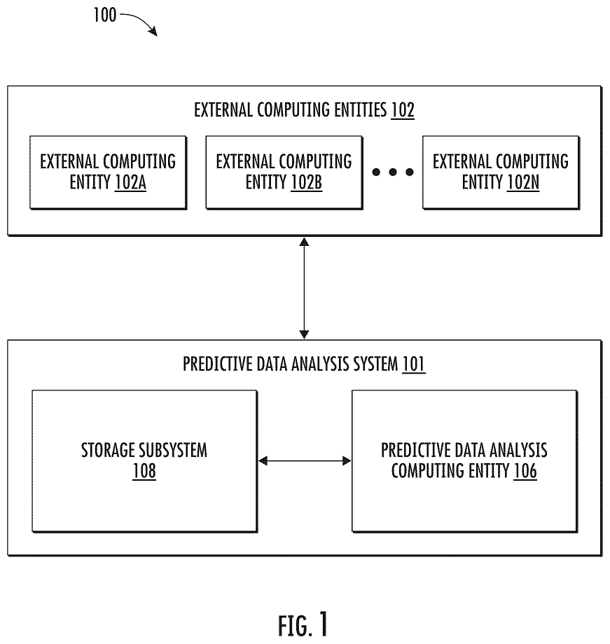

FIG. 1 provides an example overview of a system 100 that can be used to practice embodiments of the present disclosure. The system 100 includes a predictive data analysis system 101 comprising a predictive data analysis computing entity 106 configured to generate outputs that can be used to perform one or more output-based actions. The predictive data analysis system 101 may communicate with one or more external computing entities 102A-N using one or more communication networks. Examples of communication networks include any wired or wireless communication network including, for example, a wired or wireless local area network (LAN), personal area network (PAN), metropolitan area network (MAN), wide area network (WAN), or the like, as well as any hardware, software and/or firmware required to implement it (e.g., network routers, and/or the like).

The system 100 includes a storage subsystem 108 configured to store at least a portion of the data utilized by the predictive data analysis system 101. The predictive data analysis computing entity 106 may be in communication with the external computing entities 102A-N. The predictive data analysis computing entity 106 may be configured to: (i) train one or more machine learning models based on a training data store stored in the storage subsystem 108, (ii) store trained machine learning models as part of a model definition data store of the storage subsystem 108, (iii) utilize trained machine learning models to perform an action, and/or the like.

In one example, the predictive data analysis computing entity 106 may be configured to generate a prediction, classification, and/or any other data insight based on data provided by an external computing entity such as external computing entity 102A, external computing entity 102B, and/or the like.

The storage subsystem 108 may be configured to store the model definition data store and the training data store for one or more machine learning models. The predictive data analysis computing entity 106 may be configured to receive requests and/or data from at least one of the external computing entities 102A-N, process the requests and/or data to generate outputs (e.g., predictive outputs, classification outputs, and/or the like), and provide the outputs to at least one of the external computing entities 102A-N. In some embodiments, the external computing entity 102A, for example, may periodically update/provide raw and/or processed input data to the predictive data analysis system 101. The external computing entities 102A-N may further generate user interface data (e.g., one or more data objects) corresponding to the outputs and may provide (e.g., transmit, send, and/or the like) the user interface data corresponding with the outputs for presentation to the external computing entity 102A (e.g., to an end-user).

The storage subsystem 108 may be configured to store at least a portion of the data utilized by the predictive data analysis computing entity 106 to perform one or more steps/operations and/or tasks described herein. The storage subsystem 108 may be configured to store at least a portion of operational data and/or operational configuration data including operational instructions and parameters utilized by the predictive data analysis computing entity 106 to perform the one or more steps/operations described herein. The storage subsystem 108 may include one or more storage units, such as multiple distributed storage units that are connected through a computer network. Each storage unit in the storage subsystem 108 may store at least one of one or more data assets and/or one or more data about the computed properties of one or more data assets. Moreover, each storage unit in the storage subsystem 108 may include one or more non-volatile storage or memory media including but not limited to hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

The predictive data analysis computing entity 106 can include an analysis engine and/or a training engine. The predictive analysis engine may be configured to perform one or more data analysis techniques. The training engine may be configured to train the predictive analysis engine in accordance with the training data store stored in the storage subsystem 108.

### Example Predictive Data Analysis Computing Entity

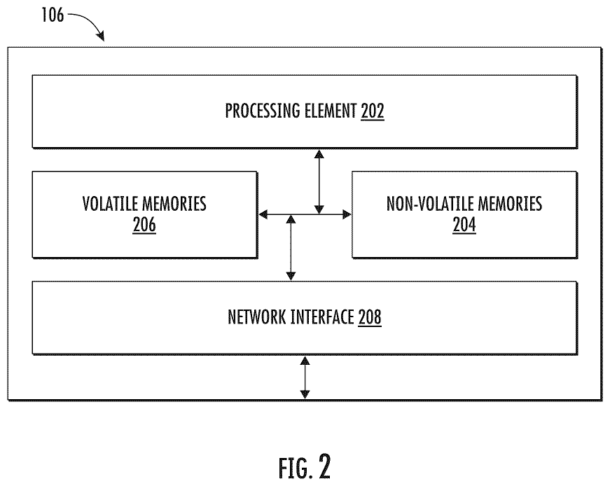

FIG. 2 provides an example predictive data analysis computing entity 106 in accordance with some embodiments discussed herein. In general, the terms computing entity, computer, entity, device, system, and/or similar words used herein interchangeably may refer to, for example, one or more computers, computing entities, desktops, mobile phones, tablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, steps/operations, and/or processes described herein. Such functions, steps/operations, and/or processes may include, for example, transmitting, receiving, operating on, processing, displaying, storing, determining, creating/generating, monitoring, evaluating, comparing, and/or similar terms used herein interchangeably. In one embodiment, these functions, steps/operations, and/or processes can be performed on data, content, information, and/or similar terms used herein interchangeably.

The predictive data analysis computing entity 106 may include a network interface 208 for communicating with various computing entities, such as by communicating data, content, information, and/or similar terms used herein interchangeably that can be transmitted, received, operated on, processed, displayed, stored, and/or the like.

In one embodiment, the predictive data analysis computing entity 106 may include or be in communication with a processing element 202 (also referred to as processors, processing circuitry, and/or similar terms used herein interchangeably) that communicate with other elements within the predictive data analysis computing entity 106 via a bus, for example. As will be understood, the processing element 202 may be embodied in a number of different ways including, for example, as at least one processor/processing apparatus, one or more processors/processing apparatuses, and/or the like.

For example, the processing element 202 may be embodied as one or more complex programmable logic devices (CPLDs), microprocessors, multi-core processors, coprocessing entities, application-specific instruction-set processors (ASIPs), microcontrollers, and/or controllers. Further, the processing element 202 may be embodied as one or more other processing devices or circuitry. The term circuitry may refer to an entirely hardware embodiment or a combination of hardware and computer program products. Thus, the processing element 202 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the processing element 202 may be configured for a particular use or configured to execute instructions stored in one or more memory elements including, for example, one or more volatile memories 206 and/or non-volatile memories 204202. As such, whether configured by hardware or computer program products, or by a combination thereof, the processing element 202 may be capable of performing steps or operations according to embodiments of the present disclosure when configured accordingly. The processing element 202, for example in combination with the one or more volatile memories 206 and/or or non-volatile memories 204, may be capable of implementing one or more computer-implemented methods described herein. In some implementations, the predictive data analysis computing entity 106 can include a computing apparatus, the processing element 202 can include at least one processor of the computing apparatus, and the one or more volatile memories 206 and/or non-volatile memories 204 can include at least one memory including program code. The at least one memory and the program code can be configured to, upon execution by the at least one processor, cause the computing apparatus to perform one or more steps/operations described herein.

The non-volatile memories 204 (also referred to as non-volatile storage, memory, memory storage, memory circuitry, media, and/or similar terms used herein interchangeably) may include at least one non-volatile memory device 204, including but not limited to hard disks, ROM, PROM, EPROM, EEPROM, flash memory, MMCs, SD memory cards, Memory Sticks, CBRAM, PRAM, FRAM, NVRAM, MRAM, RRAM, SONOS, FJG RAM, Millipede memory, racetrack memory, and/or the like.

As will be recognized, the non-volatile memories 204 may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

The one or more volatile memories (also referred to as volatile storage, memory, memory storage, memory circuitry, media, and/or similar terms used herein interchangeably) can include at least one volatile memory 206 device, including but not limited to RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like.

As will be recognized, the volatile memories 206 may be used to store at least portions of the databases, database instances, database management systems, data, applications, programs, program modules, scripts, source code, object code, byte code, compiled code, interpreted code, machine code, executable instructions, and/or the like being executed by, for example, the processing element 202. Thus, the databases, database instances, database management systems, data, applications, programs, program modules, scripts, source code, object code, byte code, compiled code, interpreted code, machine code, executable instructions, and/or the like may be used to control certain embodiments of the operation of the predictive data analysis computing entity 106 with the assistance of the processing element 202.

As indicated, in one embodiment, the predictive data analysis computing entity 106 may also include the network interface 208 for communicating with various computing entities, such as by communicating data, content, information, and/or the like that can be transmitted, received, operated on, processed, displayed, stored, and/or the like. Such communication data may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the predictive data analysis computing entity 106 may be configured to communicate via wireless client communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

### Example External Computing Entity

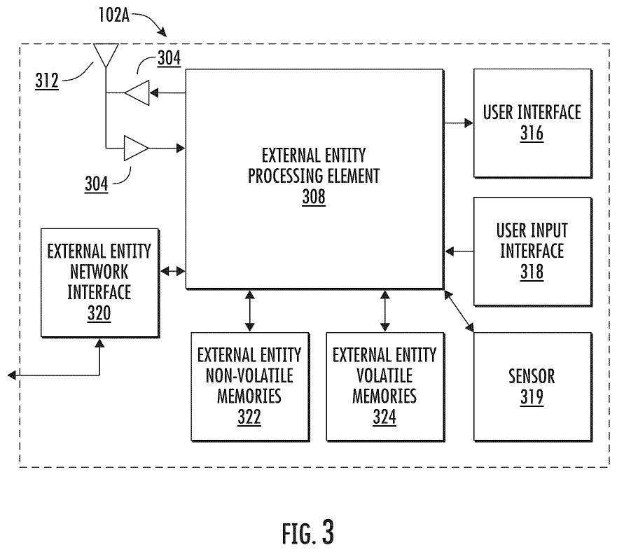

FIG. 3 provides an example external computing entity 102A in accordance with some embodiments discussed herein. In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, steps/operations, and/or processes described herein. The external computing entities 102A-N can be operated by various parties. As shown in FIG. 3, the external computing entity 102A can include an antenna 312, a transmitter 304 (e.g., radio), a receiver 306 (e.g., radio), and/or an external entity processing element 308 (e.g., CPLDs, microprocessors, multi-core processors, coprocessing entities, ASIPs, microcontrollers, and/or controllers) that provides signals to and receives signals from the transmitter 304 and the receiver 306, correspondingly. As will be understood, the external entity processing element 308 may be embodied in a number of different ways including, for example, as at least one processor/processing apparatus, one or more processors/processing apparatuses, and/or the like as described herein with reference the processing element 202.

The signals provided to and received from the transmitter 304 and the receiver 306, correspondingly, may include signaling information/data in accordance with air interface standards of applicable wireless systems. In this regard, the external computing entity 102A may be capable of operating with one or more air interface standards, communication protocols, modulation types, and access types. More particularly, the external computing entity 102A may operate in accordance with any of a number of wireless communication standards and protocols, such as those described above with regard to the predictive data analysis computing entity 106. In a particular embodiment, the external computing entity 102A may operate in accordance with multiple wireless communication standards and protocols, such as UMTS, CDMA2000, 1×RTT, WCDMA, GSM, EDGE, TD-SCDMA, LTE, E-UTRAN, EVDO, HSPA, HSDPA, Wi-Fi, Wi-Fi Direct, WiMAX, UWB, IR, NFC, Bluetooth, USB, and/or the like. Similarly, the external computing entity 102A may operate in accordance with multiple wired communication standards and protocols, such as those described above with regard to the predictive data analysis computing entity 106 via an external entity network interface 320.

Via these communication standards and protocols, the external computing entity 102A can communicate with various other entities using means such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). The external computing entity 102A can also download changes, add-ons, and updates, for instance, to its firmware, software (e.g., including executable instructions, applications, program modules), operating system, and/or the like.

According to one embodiment, the external computing entity 102A may include location determining embodiments, devices, modules, functionalities, and/or the like. For example, the external computing entity 102A may include outdoor positioning embodiments, such as a location module adapted to acquire, for example, latitude, longitude, altitude, geocode, course, direction, heading, speed, universal time (UTC), date, and/or various other information/data. In one embodiment, the location module can acquire data such as ephemeris data, by identifying the number of satellites in view and the relative positions of those satellites (e.g., using global positioning systems (GPS)). The satellites may be a variety of different satellites, including Low Earth Orbit (LEO) satellite systems, Department of Defense (DOD) satellite systems, the European Union Galileo positioning systems, the Chinese Compass navigation systems, Indian Regional Navigational satellite systems, and/or the like. This data can be collected using a variety of coordinate systems, such as the DecimalDegrees (DD); Degrees, Minutes, Seconds (DMS); Universal Transverse Mercator (UTM); Universal Polar Stereographic (UPS) coordinate systems; and/or the like. Alternatively, the location information/data can be determined by triangulating a position of the external computing entity 102A in connection with a variety of other systems, including cellular towers, Wi-Fi access points, and/or the like. Similarly, the external computing entity 102A may include indoor positioning embodiments, such as a location module adapted to acquire, for example, latitude, longitude, altitude, geocode, course, direction, heading, speed, time, date, and/or various other information/data. Some of the indoor systems may use various position or location technologies including RFID tags, indoor beacons or transmitters, Wi-Fi access points, cellular towers, nearby computing devices (e.g., smartphones, laptops) and/or the like. For instance, such technologies may include the iBeacons, Gimbal proximity beacons, Bluetooth Low Energy (BLE) transmitters, NFC transmitters, and/or the like. These indoor positioning embodiments can be used in a variety of settings to determine the location of someone or something to within inches or centimeters.

The external computing entity 102A may include a user interface 316 (e.g., a display, speaker, and/or the like) that can be coupled to the external entity processing element 308. In addition, or alternatively, the external computing entity 102A can include a user input interface 319 (e.g., keypad, touch screen, microphone, and/or the like) coupled to the external entity processing element 308).

For example, the user interface 316 may be a user application, browser, and/or similar words used herein interchangeably executing on and/or accessible via the external computing entity 102A to interact with and/or cause the display, announcement, and/or the like of information/data to a user. The user input interface 318 can comprise any of a number of input devices or interfaces allowing the external computing entity 102A to receive data including, as examples, a keypad (hard or soft), a touch display, voice/speech interfaces, motion interfaces, and/or any other input device. In embodiments including a keypad, the keypad can include (or cause display of) the conventional numeric (0-9) and related keys (#, *, and/or the like), and other keys used for operating the external computing entity 102A and may include a full set of alphabetic keys or set of keys that may be activated to provide a full set of alphanumeric keys. In addition to providing input, the user input interface 318 can be used, for example, to activate or deactivate certain functions, such as screen savers, sleep modes, and/or the like.

The external computing entity 102A can also include one or more external entity non-volatile memories 322 and/or one or more external entity volatile memories 324, which can be embedded within and/or may be removable from the external computing entity 102A. As will be understood, the external entity non-volatile memories 322 and/or the external entity volatile memories 324 may be embodied in a number of different ways including, for example, as described herein with reference the non-volatile memories 204 and/or the external volatile memories 206.

### III. Example System Operations

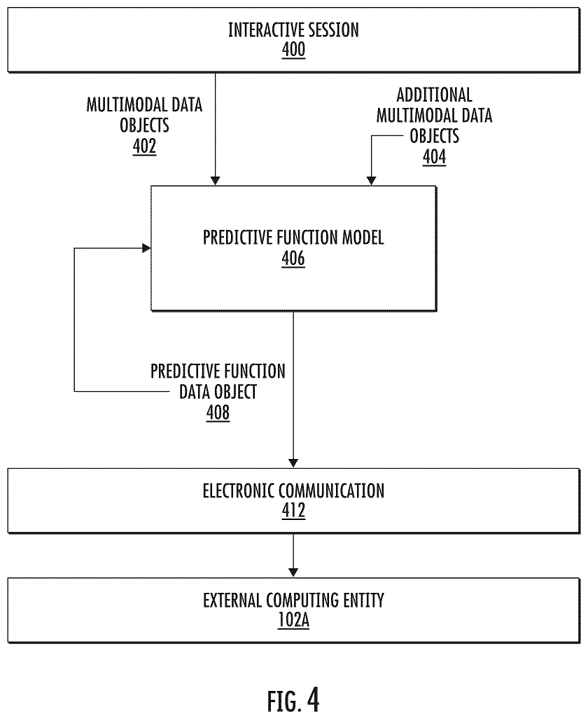

FIG. 4 describes example system operations and data flows in accordance with one or more embodiments discussed herein. In some embodiments, the operations described with reference to FIG. 4 may be performed by one or more of a predictive data analysis system 101 and/or one or more external computing entities 102A-N.

In some embodiments, an interactive session 400 is associated with an interaction involving a subject entity, one or more additional entities, and one or more electronic devices, such as a web camera, personal computer, mobile telephone, smart watch, online communication vehicle, and/or the like. In some embodiments, the interactive session 400 may take place in an online context, such as a virtual meeting. In some embodiments, the operations described herein are performed iteratively, wherein each iterative execution of these operations consider the subject entity to be a different entity of the plurality of entities engaged in the interactive session 400. In this regard, for example, for an interactive session 400 comprising entity A and entity B, the operations described herein are performed wherein entity A is considered the subject entity, and entity B is considered the additional entity. In this example, the operations described herein are performed again, wherein entity B is considered the subject entity, and entity A is considered the additional entity. In this way, each entity of the plurality of entities associated with the interactive session 400 are analyzed in the context of being both the subject and a respondent (e.g., a leader and a follower), as the nature of virtual meetings tends to comprise a plurality of different leaders, speakers, presenters, stakeholders, and observers.

In some embodiments, the predictive data analysis system 101 is configured to generate one or more multimodal data objects 402 based on the interactive session 400 and the subject entity. In some embodiments, the predictive data analysis system 101 is configured to generate one or more multimodal data objects 402 based on the interactive session 400 and one or more additional entities. In some embodiments, the predictive data analysis system 101 is configured to generate one or more multimodal data objects 402 based on one or more interactions with one or more electronic devices by the subject entity and/or one or more additional entities. The one or more multimodal data objects 402 are configured to be generated based on one or more of virtual meeting video data, virtual meeting audio data, electronic mail messages, short message service (SMS) texts, virtual meeting chat messages, transcribed speech, rich communication services (RCS), electronic image data, instant message data, online communication vehicles, and/or the like. In an instance in which virtual meeting video data is available for analysis, the one or more multimodal data objects 402 are configured to indicate one or more facial expression event markers and/or body language event markers by detecting visual signals in the virtual meeting video data. In an instance in which virtual meeting audio data is available for analysis, the one or more multimodal data objects 402 are configured to indicate one or more tone of voice event markers and/or pitch of voice event markers by detecting auditory signals in the virtual meeting audio data. In an instance in which electronic mail messages, SMS texts, virtual meeting chat messages, transcribed speech and/or the like are available for analysis, the one or more multimodal data objects 402 are configured to indicate one or more semantic event markers and/or syntactical event markers by detecting textual signals in the textual data. In some embodiments, the one or more multimodal data objects 402 are configured to indicate one or more attention network event markers by detecting attention signals. In this regard, for example, the one or more attention network event markers may indicate that an additional entity is facing, looking at, or is otherwise attentive to a subject entity. Similarly, the one or more attention network event markers may indicate that the subject entity is facing, looking at, or is otherwise attentive to an additional entity.

In some embodiments, the one or more multimodal data objects 402 are configured to indicate demographic data associated with one or more entities.

In some embodiments, the one or more event markers indicated by one or more multimodal data objects are configured to enable training and/or updating of a predictive function model. According to certain embodiments, event markers can indicate a start and end time of an interactive session, a time that a photo is captured and/or transmitted, a time that an email, chat message, or other communication is transmitted, or the like. The event markers may therefore provide a timing parameter within the multimodal data objects 402, or amongst a plurality of multimodal data objects 402 that enable the predict function model to identify and predict patterns occurring over time and using a holistic perspective of a subject's interactions, represented by a sequence of multimodal data objects having respective one or more event markers. In some embodiments, the timing parameter of the one or more event markers may indicate an event marker duration. In this regard, for example, a timing parameter of a facial expression event marker may indicate that a subject entity exhibited a smile for a duration of three seconds.

In some embodiments, a predictive function model 406 is configured to receive one or more multimodal data objects 402. In some embodiments, the predictive function model 406 is trained, customized, and fine-tuned based on a plurality of annotated multimodal data objects. According to certain embodiments, a sequence of multimodal data objects is ingested by the predictive function model such that respective events markers can be used to infer trends over time and make predictions with regard to functions occurring on a timeline or within anticipated timeframes. Annotated multimodal data objects are expertly labeled data objects curated specifically as training data for the predictive function model 406. Annotated multimodal data objects and are generated based on accurate, context-sensitive analysis of complex behavioral cues found in leadership communication, as well as research-backed behavioral taxonomies to ensure that the predictive function model 406 is grounded in both industry-accepted theoretical frameworks and practical relevance. Generic systems and methods of evaluating leader behaviors may overlook subtle indicators of leadership styles (e.g., charisma, ethical tone, and/or transformational intent) because they are not specifically trained on annotated multimodal data objects. Example embodiments therefore provide technical improvements to such machine learning models by improving the accuracy of predictive function data objects. By training the machine learning model based on the annotated multimodal data objects, the machine learning models are enabled to generate predictive function data objects in a specialized manner, leading to improved outputs capable of predicting behavioral patterns over time, predicting responses to subject entity actions, and predicting emotions evoked by a subject entity's behavioral cues with improved accuracy.

In some embodiments, by fine tuning the predictive function model 406 based on annotated multimodal data objects, the predictive function model 406 is configured to recognize nuanced leadership signals, consistently infer effects of subject entity behaviors on additional entity responses across a plurality of contexts, and generate more reliable insights via predictive function data objects. In some embodiments, the predictive function model 406 is configured to be generated and updated based on one or more training parameters. In some embodiments, the one or more training parameters comprise one or more hyperparameters. In some embodiments, hyperparameter tuning of the predictive function model 406 is configured to optimize the performance and accuracy of the predictive function model 406. In some embodiments, the hyperparameters comprise a batch size, a number of epochs, a learning rate multiplier, and/or the like. In some embodiments, a grid search approach is used to fine tune each hyperparameter. In some embodiments, the predictive function model 406 is a large language model. In some embodiments, the predictive function model 406 is a transfer learning model.

In some embodiments, a plurality of predictive function models are trained and fine tuned by adjusting the one or more training parameters. Each of the plurality of predictive function models are evaluated based on a test dataset and one or more performance metrics. In some embodiments, the one or more performance metrics used to evaluate the machine learning model include one or more of the following: an accuracy feature, which quantifies the proportion of correctly predicted instances over the total number of instances; an F1 score feature, which represents the harmonic mean of precision and recall, providing a balanced measure of a model's performance, especially in cases of class imbalance; a precision feature, indicating the ratio of true positive predictions to the total predicted positives, useful for minimizing false positives; a recall feature, measuring the ratio of true positives to all actual positives, critical for minimizing false negatives; a Matthews Correlation Coefficient (MCC) feature, which offers a comprehensive metric that takes into account true and false positives and negatives and is particularly informative for binary classification tasks with imbalanced datasets; a Cohen's Kappa feature, which assesses the agreement between predicted and actual classifications while accounting for chance agreement; and/or other suitable statistical or domain-specific metrics that reflect the model's predictive performance. In some embodiments, a model of the plurality of predictive function models, such as the best performing model is automatically selected to be the predictive function model 406.

In some embodiments, the one or more multimodal data objects 402 are applied to the predictive function model 406. In some embodiments, the predictive function model 406 is configured to generate a predictive function data object 408 based on the one or more multimodal data objects 402. In some embodiments, the predictive function data object 408 indicates an extent to which one or more predictive functions are associated with the one or more multimodal data objects 402. In some embodiments, the predictive function data object 408 indicates one or more responses evoked by the one or more multimodal data objects 402.

In some embodiments, the one or more predictive functions comprise a charismatic leadership feature. In some embodiments, charismatic leadership is signaled through verbal behaviors such as metaphors, similes, anecdotes, and rhetorical questions. In some embodiments, the charismatic leadership feature is indicative of an extent to which the subject entity embodies a charismatic leadership quality based on the one or more multimodal data objects 402.

In some embodiments, the one or more predictive functions comprise an ethical leadership feature. In some embodiments, ethical leadership is signaled through behavior by the leader targeted at stakeholders comprising the enactment of prosocial values combined with expressions of moral emotions, and is marked by verbal behaviors regarding morals, rules, fairness, and positive communication. In some embodiments, the ethical leadership feature is indicative of an extent to which the subject entity embodies an ethical leadership quality based on the one or more multimodal data objects 402.

In some embodiments, the one or more predictive functions comprise a transformational leadership feature. In some embodiments, transformational leadership is signaled through developmental and prosocial behaviors tailored for each unique stakeholder and is marked by verbal behaviors such as sharing life lessons and speaking words of affirmation. In some embodiments, the transformational leadership feature is indicative of an extent to which the subject entity embodies a transformational leadership quality based on the one or more multimodal data objects 402.

In some embodiments, the one or more predictive functions comprise a destructive leadership feature. In some embodiments, destructive leadership is signaled through behavior that is hostile and destructive, and is marked by threatening, abusive, narcissistic, or Machiavellian expressions, as well as lack of professional decorum and use of favoritism. In some embodiments, the destructive leadership feature is indicative of an extent to which the subject entity embodies a destructive leadership quality based on the one or more multimodal data objects 402.

In some embodiments, the one or more predictive functions comprise a supportive followership feature. In some embodiments, supportive followership is signaled through behaviors such as vocal endorsement and reaffirming commitment. In some embodiments, the supportive followership feature is indicative of an extent to which the subject entity embodies a supportive followership quality based on the one or more multimodal data objects 402.

In some embodiments, the one or more predictive functions comprise an authentic leadership feature. In some embodiments, authentic leadership is signaled through behaviors such as ownership and accountability statements and building trust with consistency across behavioral statements. In some embodiments, the authentic leadership feature is indicative of an extent to which the subject entity embodies an authentic leadership quality based on the one or more multimodal data objects 402.

In some embodiments, the one or more predictive functions comprise an effective leadership feature. In some embodiments, effective leadership is signaled through behaviors such as idea generation and statements that support continuous improvement. In some embodiments, the effective leadership feature is indicative of an extent to which the subject entity embodies an effective leadership quality based on the one or more multimodal data objects 402.

In some embodiments, the one or more predictive functions comprise a transactional leadership feature. In some embodiments, transactional leadership is signaled through behaviors that involve making statements that establish desired goals and what followers will earn upon achieving those goals. In some embodiments, the transactional leadership feature is indicative of an extent to which the subject entity embodies a transactional leadership quality based on the one or more multimodal data objects 402.

In some embodiments, the one or more predictive functions comprise a shared leadership feature. In some embodiments, shared leadership is signaled through behaviors that delegate and provide opportunities to others to take on leadership roles. In some embodiments, the shared leadership feature is indicative of an extent to which the subject entity embodies a shared leadership quality based on the one or more multimodal data objects 402.

In some embodiments, the predictive function data object 408 is configured to be provided to the predictive function model 406 to enable updating, retraining, and/or fine tuning of the predictive function model 406. In some embodiments, the predictive function data object 408 is annotated to maintain a high level of quality of the data being used to update the predictive function model 406.

In some embodiments, the predictive function model 406 is configured to determine one or more additional entity responses (e.g., emotions, reactions, changes in behavior, changes in demeanor, changes in facial expression, changes in body language, and/or the like) evoked by the subject entity associated with the one or more multimodal data objects 402. In this regard, for example, the subject entity states “anyone wearing a blue shirt will receive a 5% raise.” In this example, the predictive function model 406 may determine that this statement evoked a positive response from a first additional entity through analysis of a first example multimodal data object associated with the first additional entity, wherein the first example multimodal data object indicated that a facial expression event marker of the first additional entity changed from neutral to a smile. Continuing this example, the predictive function model 406 may determine that this statement evoked a negative response from a second additional entity through analysis of a second example multimodal data object associated with the second additional entity, wherein the second example multimodal data object indicated that a virtual chat message sent by the second additional entity stated “I wore a blue shirt yesterday: (”.

In some embodiments, the predictive data analysis system 101 is configured to generate an electronic communication 412 configured for display via a display device. In some embodiments, the electronic communication 412 is configured to be generated based on the predictive function data object 408. In some embodiments, the electronic communication 412 is transmitted to a computing device associated with the subject entity, such as the external computing entity 102A. In some embodiments, the electronic communication 412 is transmitted to a computing device associated with one or more additional entities.

In some embodiments, the predictive data analysis system 101 is configured to perform one or more actions based on the predictive function data object. For example, the predictive data analysis system 101 is configured to determine one or more subject entity behavior improvement features. In some embodiments, a subject entity behavior improvement feature is configured to improve the leadership and communication skills of the subject entity. In some embodiments, an electronic communication 412 comprising the subject entity behavior improvement feature is displayed to the subject entity via user interface 316 of the external computing entity 102A. In some embodiments, the electronic communication 412 may be configured as a real-time alert displayed to the subject entity during a virtual meeting. In some embodiments, the electronic communication 412 comprising one or more subject entity behavior improvement features may be displayed to the subject entity subsequent to the interactive session 400. In this regard, for example, the subject entity behavior improvement feature may alert the subject entity that they are speaking with too many filler words. As another example, the subject entity behavior improvement feature may alert the subject entity that they utilized a destructive leadership tactic. As another example, the subject entity behavior improvement feature may alert the subject entity that they evoked a negative response from one or more additional entities.

In some embodiments, the predictive data analysis system 101 being configured to perform one or more actions based on the predictive function data object further comprises the predictive data analysis system 101 being configured to determine one or more team composition features. In some embodiments, a team composition feature is configured to improve the cohesion, chemistry, collaboration, communication, and/or the like between one or more entities associated with one or more structural data objects. In some embodiments, a structural data object represents a composition of a subject entity and one or more additional entities. In this regard, for example, a structural data object may indicate that a subject entity and one or more additional entities are associated as a team, group, class, company, and/or the like. In some embodiments, an electronic communication 412 comprising the team composition feature is displayed to one or more entities associated with a structural data object via user interfaces 316 of the external computing entities 102A-N. In some embodiments, the electronic communication 412 may be configured as a real-time alert displayed to one or more entities associated with a structural data object during a virtual meeting. In this regard, for example, the team composition feature may alert one or more entities associated with a structural data object that one entity tends to interrupt another entity. As another example, the team composition feature may alert one or more entities associated with a structural data object that one entity is speaking too much. Conversely, the team composition feature may alert one or more entities associated with a structural data object that one entity is not contributing. As another example, the team composition feature may alert one or more entities associated with a structural data object that one or more entities tend to work well together. As another example, the team composition feature may alert one or more entities associated with a structural data object that one or more entities tend to clash.

In some embodiments, the predictive data analysis system 101 being configured to perform one or more actions based on the predictive function data object further comprises the predictive data analysis system 101 being configured to reconfigure a composition of a structural data object based on the team composition feature. In some embodiments, reconfiguring a composition of a structural data object may comprise reconfiguring a hierarchical data structure, removing specific elements, relocating elements to different branches, modifying node relationships, and/or similar structural adjustments. In this regard, example embodiments may be used to reorganize digital resources, optimize data architectures, or restructure system configurations based on predictive outputs. In this regard, example embodiments may be used to reconfigure, or reorganize, clusters of resources, such as but not limited to human resources represented in an electronic structural data object having a hierarchical format. In this regard, for example, the predictive data analysis system 101 may be configured to remove an association of the subject entity and/or one or more additional entities from a structural data object. As another example, the predictive data analysis system 101 may be configured to add as association of the subject entity and/or one or more additional entities to a structural data object.

In some embodiments, the predictive data analysis system is configured to generate one or more additional multimodal data objects 404. In some embodiments, a subject entity participates in a plurality of interactive sessions, triggering the generation of additional multimodal data objects 404 by the predictive data analysis system 101, further triggering the generation of additional predictive function data objects by the predictive function model 406, and further triggering the generation of additional electronic communications by the predictive data analysis system 101. In some embodiments, each of these additional system outputs are used to further update and fine-tune the predictive function model 406.

In some embodiments, the predictive data analysis system is configured to generate a subject entity profile. In some embodiments, the additional multimodal data objects 404 are applied to the predictive function model 406 to generate the subject entity profile. The subject entity profile is configured to encapsulate personalized historical data, trends, and changes in the subject entity's leadership skills, traits, qualities, and performance over time. In some embodiments, the electronic communication 412 is generated based at least in part on the subject entity profile. In some embodiments, the predictive function model 406 is configured to generate the predictive function data object 408 based at least in part on the subject entity profile.

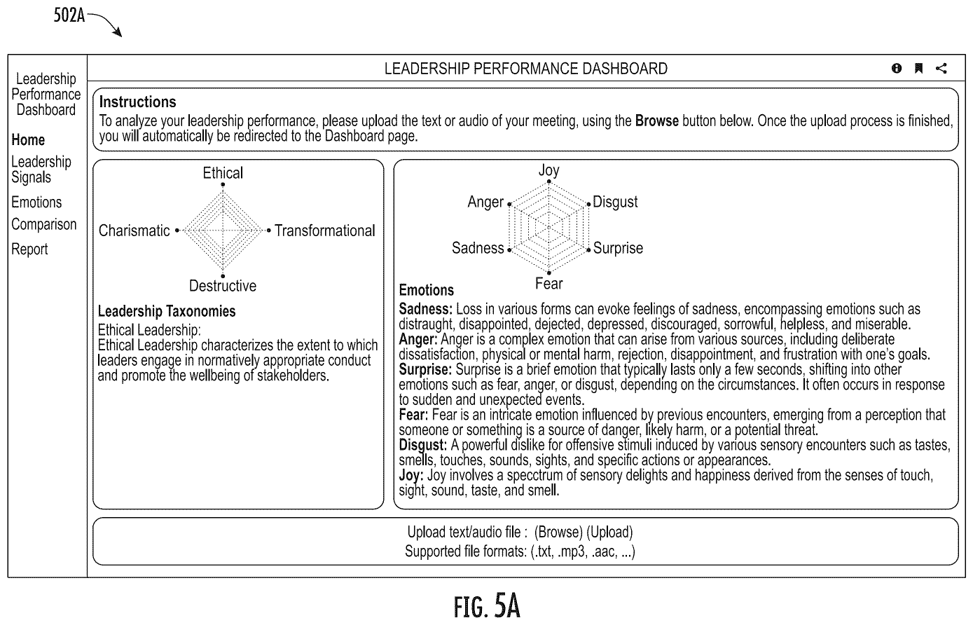

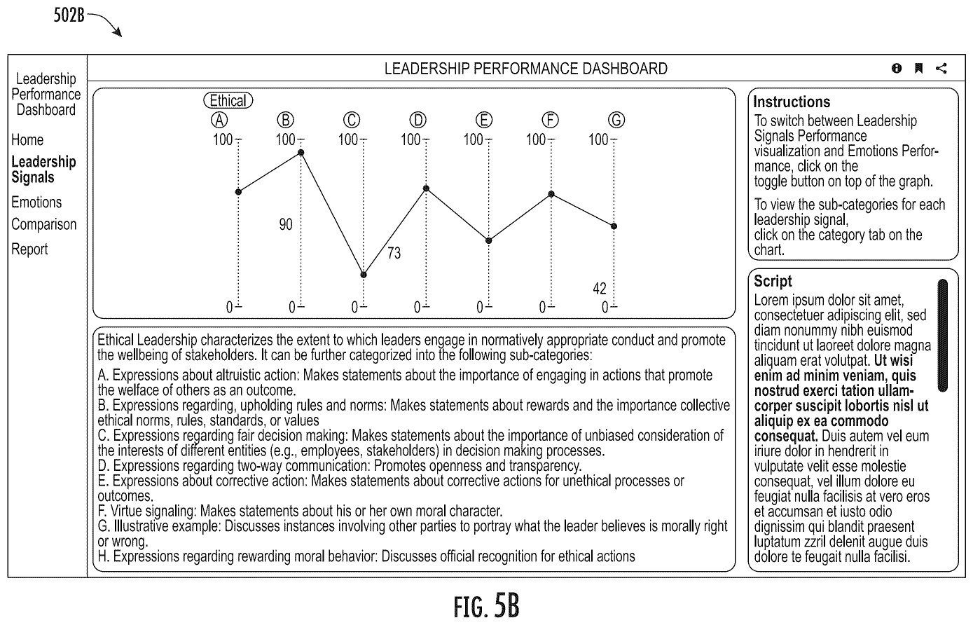

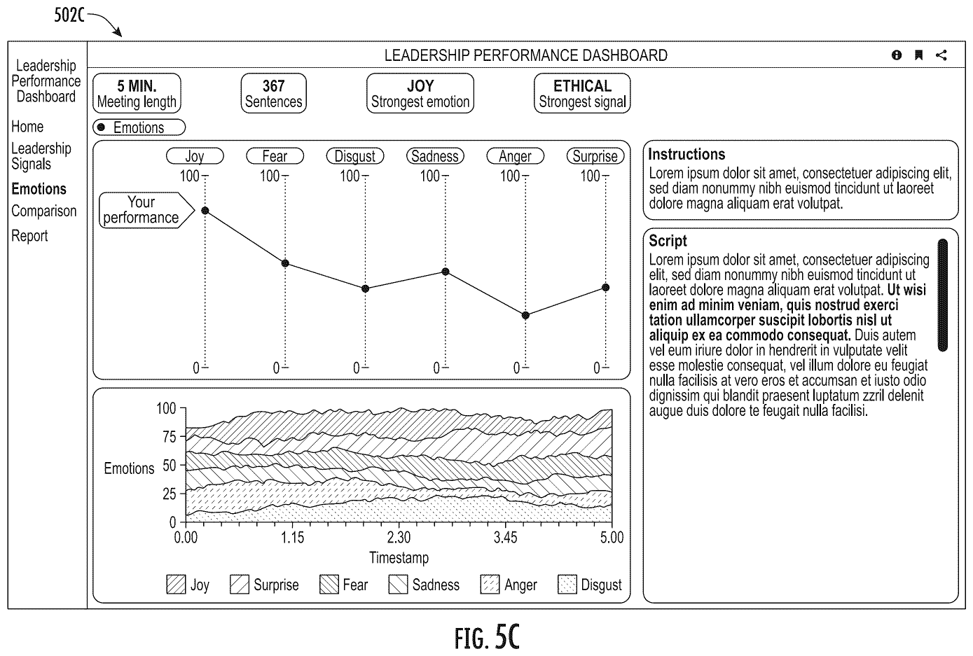

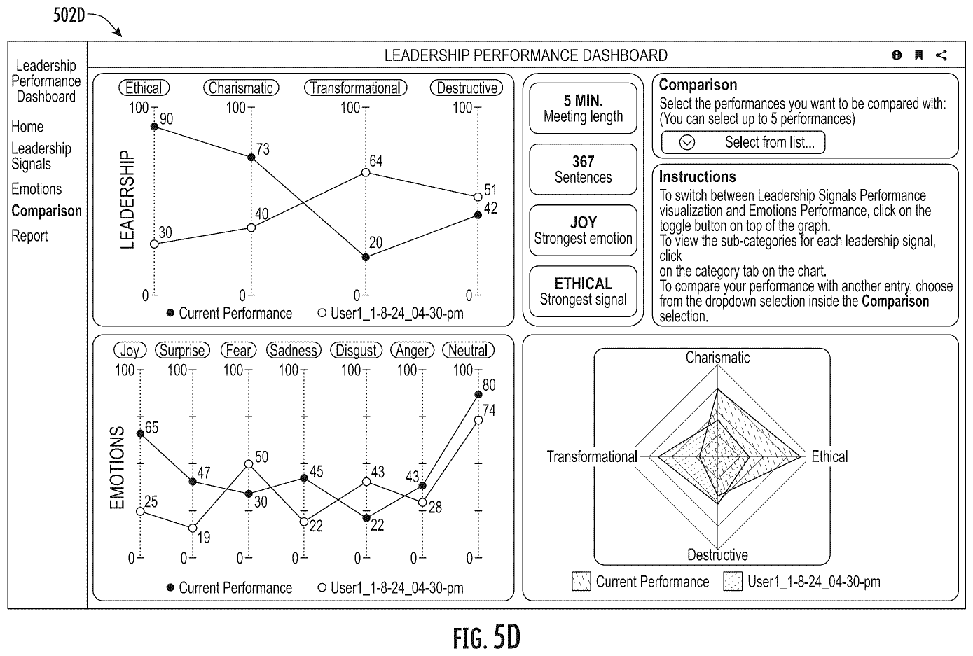

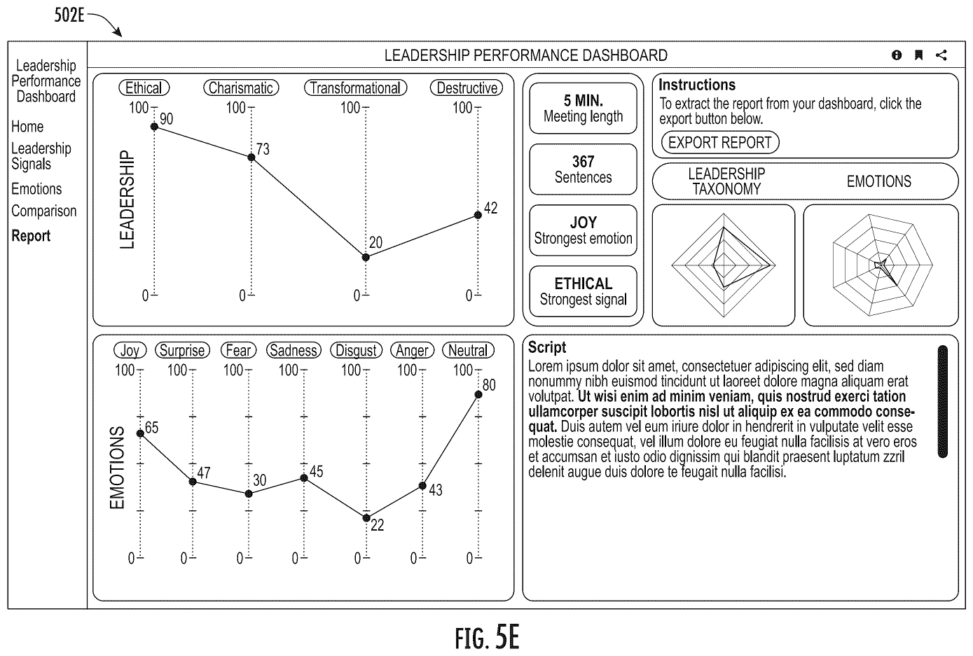

In some embodiments, generating the electronic communication 412 comprises generating one or more subject entity performance interface components 502. FIGS. 5A-5E illustrate example subject entity performance interface components 502A-E. In some embodiments, the one or more subject entity performance interface components 502 are configured to render a visual representation of the electronic communication 412 to a display of a computing device associated with the subject entity, such as user interface 316 of the external computing entity 102A.

The depicted subject entity performance interface component 502A illustrates example interfaces relating to a subject entity's subject entity profile. For example, subject entity performance interface component 502A enables a subject entity to visualize historical data regarding the behavioral taxonomies embodied in the subject entity's behaviors and leadership styles. Additionally, subject entity performance interface component 502A enables a subject entity to visualize historical data regarding the emotions evoked from additional entities by the subject entity's behaviors and leadership styles.

The depicted subject entity performance interface component 502B illustrates example interfaces relating to a subject entity's subject entity profile. For example, subject entity performance interface component 502B enables a subject entity to visualize historical data regarding the leadership signals derived from multimodal data objects and predictive function data objects. Example leadership signals include expressions about altruistic action, expressions regarding upholding rules and norms, expressions regarding fair decision making, expressions regarding two-way communication, expressions about corrective action, virtue signaling, illustrative examples, and expressions regarding rewarding moral behavior. Additionally, subject entity performance interface component 502B enables a subject entity to visualize specific leadership signals resulting from specific multimodal data objects, such as specific sentences of transcribed speech from a virtual meeting.

The depicted subject entity performance interface component 502C illustrates example interfaces relating to a subject entity's subject entity profile. For example, subject entity performance interface component 502C enables a subject entity to visualize behavioral and response data regarding a specific interactive session 400. This enables the subject entity to visualize the real-world impacts that their words and actions have on one or more additional entities during a specific interactive session 400.

The depicted subject entity performance interface component 502D illustrates example interfaces relating to a subject entity's subject entity profile. For example, subject entity performance interface component 502D enables a subject entity to compare their own leadership performance against other leadership performances. In some embodiments, the other leadership performance may be a leadership performance from a specific interactive session 400. In some embodiments, the other leadership performance may be associated with a different entity, such as a famous person known for their strong leadership skills.

The depicted subject entity performance interface component 502E illustrates example interfaces relating to a subject entity's subject entity profile. For example, subject entity performance interface component 502E enables a subject entity to visualize their own leadership performance. In some embodiments, the subject entity performance interface component 502E illustrates an extent to which the subject entity exhibits one or more behavioral taxonomies. In some embodiments, the subject entity performance interface component 502E illustrates an extent to which the subject entity conveys one or more emotions. In some embodiments, the subject entity performance interface component 502E illustrates an extent to which the subject entity evokes one or more emotions from one or more additional entities.

### IV. Example Methods

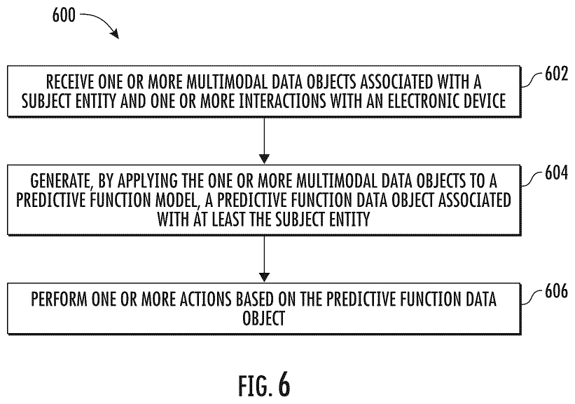

Referring now to FIG. 6, a flowchart providing an example method 600 is illustrated. In this regard, FIG. 6 illustrates operations that may be performed by the predictive data analysis system 101 and/or one or more components of the predictive data analysis system 101, in concert with one or more external computing entities 102 and/or one or more components of the one or more external computing entities 102. In some embodiments, the example method 600 defines a computer-implemented process, which may be executable by any of the device(s) and/or system(s) embodied in hardware, software, firmware, and/or a combination thereof, as described herein. In some embodiments, computer program code including one or more computer-coded instructions are stored to at least one non-transitory computer-readable storage medium, such that execution of the computer program code initiates performance of the method 600.

At operation 602, the method 600 includes receiving one or more multimodal data objects. In some embodiments, the one or more multimodal data objects are associated with a subject entity and one or more interactions with an electronic device.

As described above, in some embodiments, the predictive data analysis system 101 is configured to generate one or more multimodal data objects 402 based on the interactive session 400 and the subject entity. In some embodiments, the predictive data analysis system 101 is configured to generate one or more multimodal data objects 402 based on the interactive session 400 and one or more additional entities. In some embodiments, the predictive data analysis system 101 is configured to generate one or more multimodal data objects 402 based on one or more interactions with one or more electronic devices by the subject entity and/or one or more additional entities. The one or more multimodal data objects 402 are configured to be generated based on one or more of virtual meeting video data, virtual meeting audio data, electronic mail messages, short message service (SMS) texts, virtual meeting chat messages, transcribed speech, rich communication services (RCS), electronic image data, instant message data, online communication vehicles, and/or the like. In an instance in which virtual meeting video data is available for analysis, the one or more multimodal data objects 402 are configured to indicate one or more facial expression event markers and/or body language event markers. In an instance in which virtual meeting audio data is available for analysis, the one or more multimodal data objects 402 are configured to indicate one or more tone of voice event markers and/or pitch of voice event markers. In an instance in which electronic mail messages, SMS texts, virtual meeting chat messages, transcribed speech and/or the like are available for analysis, the one or more multimodal data objects 402 are configured to indicate one or more semantic event markers and/or syntactical event markers. In some embodiments, the one or more event markers indicated by one or more multimodal data objects are configured to enable training and/or updating of a predictive function model. According to certain embodiments, event markers can indicate a start and end time of an interactive session, a time that a photo is captured and/or transmitted, a time that an email, chat message, or other communication is transmitted, or the like. The event markers may therefore provide a timing parameter within the multimodal data objects 402, or amongst a plurality of multimodal data objects 402 that enable the predict function model to identify and predict patterns occurring over time and using a holistic perspective of a subject's interactions, represented by a sequence of multimodal data objects having respective one or more event markers.

At operation 604, the method 600 includes generating, by applying the one or more multimodal data objects to a predictive function model, a predictive function data object. In some embodiments, the predictive function data object is associated with at least the subject entity. In some embodiments, the predictive function data object is also associated with one or more additional entities.

As described above, in some embodiments, the one or more multimodal data objects 402 are applied to the predictive function model 406. In some embodiments, the predictive function model 406 is configured to generate a predictive function data object 408 based on the one or more multimodal data objects 402. In some embodiments, the predictive function data object 408 indicates an extent to which one or more predictive functions are associated with the one or more multimodal data objects 402. In some embodiments, the predictive function data object 408 indicates one or more responses evoked by the one or more multimodal data objects 402. In some embodiments, the predictive function data object 408 is configured to update the predictive function model 406.

At operation 606, the method 600 includes performing one or more actions based on the predictive function data object. In some embodiments, performing one or more actions based on the predictive function data object comprises generating one or more subject entity performance interface components and causing rendering of the one or more subject entity performance interface components via a display device of the electronic device associated with the subject entity. In some embodiments, performing one or more actions based on the predictive function data object comprises generating an electronic communication indicating at least one of one or more subject entity behavior improvement features, or a team composition feature. In some embodiments, performing one or more actions based on the predictive function data object comprises reconfiguring a composition of one or more structural data objects. In some embodiments, performing one or more actions based on the predictive function data object comprises causing rendering of the electronic communication via a display device of the electronic device associated with the subject entity in real time during a virtual meeting.

### V. Conclusion

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

1. A system comprising one or more processors, and memory having instructions that, when executed by the one or more processors, cause the one or more processors to:
receive one or more multimodal data objects associated with a subject entity and one or more interactions with an electronic device;
generate, by applying the one or more multimodal data objects to a predictive function model, a predictive function data object associated with at least the subject entity; and
perform one or more actions based on the predictive function data object.

2. The system of claim 1, wherein the one or more multimodal data objects are associated with a respective one or more event markers, and wherein the instructions that, when executed by the one or more processors, further cause the one or more processors to:
update the predictive function model by applying a sequence of multimodal data objects having respective one or more event markers.

3. The system of claim 1, wherein the one or more multimodal data objects are further associated with one or more additional entities, and wherein the predictive function data object is further associated with the one or more additional entities.

4. The system of claim 3, wherein the predictive function data object is associated with inter-related functions of a plurality of entities.

5. The system of claim 1, wherein the one or more multimodal data objects are derived from one or more of electronic mail messages, short message service (SMS) texts, video data, rich communication services (RCS), electronic images, instant message data, chat data, virtual meeting interaction data, audio data, or online communication vehicles.

6. The system of claim 1, wherein the instructions that, when executed by the one or more processors, further cause the one or more processors to:
receive one or more annotated multimodal data objects;
generate the predictive function model based on the one or more annotated multimodal data objects; and
update the predictive function model based on one or more training parameters.

7. The system of claim 1, wherein the predictive function data object is associated with one or more of a charismatic leadership feature, an ethical leadership feature, a transformational leadership feature, a shared leadership feature, a transactional leadership feature, an authentic leadership feature, a destructive leadership feature, an effective leadership feature, or a supportive followership feature.

8. The system of claim 1, wherein the predictive function model comprises a large language model.

9. The system of claim 1, wherein performing one or more actions based on the predictive function data object comprises:
generating one or more subject entity performance interface components; and
causing rendering of the one or more subject entity performance interface components via a display device of the electronic device associated with the subject entity.

10. The system of claim 1, wherein performing one or more actions based on the predictive function data object comprises:
generating an electronic communication indicating at least one of one or more subject entity behavior improvement features, or a team composition feature.

11. The system of claim 1, wherein performing one or more actions based on the predictive function data object comprises:
reconfiguring a composition of one or more structural data objects.

12. The system of claim 10, wherein the instructions that, when executed by the one or more processors, further cause the one or more processors to:
cause rendering of the electronic communication via a display device of the electronic device associated with the subject entity in real time during a virtual meeting.

13. The system of claim 1, wherein the instructions that, when executed by the one or more processors, further cause the one or more processors to:
receive one or more additional multimodal data objects associated with a subject entity and one or more interactions with an electronic device;
generate, by applying the one or more additional multimodal data objects to the predictive function model, a subject entity profile associated with at least the subject entity;
generate, based on the subject entity profile, an electronic communication configured for display via a display device; and
transmit the electronic communication to the electronic device associated with the subject entity.

14. A computer-implemented method comprising:
receiving one or more multimodal data objects associated with a subject entity and one or more interactions with an electronic device;
generating, by applying the one or more multimodal data objects to a predictive function model, a predictive function data object associated with at least the subject entity; and
perform one or more actions based on the predictive function data object.

15. The computer-implemented method of claim 14, wherein the one or more multimodal data objects are associated with a respective one or more event markers, further comprising:
updating the predictive function model by applying a sequence of multimodal data objects having respective one or more event markers.

16. The computer-implemented method of claim 14, wherein the one or more multimodal data objects are further associated with one or more additional entities, and wherein the predictive function data object is further associated with the one or more additional entities.

17. The computer-implemented method of claim 14, wherein the one or more multimodal data objects are derived from one or more of electronic mail messages, short message service (SMS) texts, video data, rich communication services (RCS), electronic images, instant message data, chat data, virtual meeting interaction data, audio data, or online communication vehicles.

18. The computer-implemented method of claim 14, further comprising:
receiving one or more annotated multimodal data objects;
generating the predictive function model based on the one or more annotated multimodal data objects; and
updating the predictive function model based on one or more training parameters.

19. The computer-implemented method of claim 14, wherein performing one or more actions based on the predictive function data object comprises:
generating an electronic communication indicating at least one of one or more subject entity behavior improvement features, or a team composition feature.

20. A non-transitory computer readable medium having instructions that, when executed by one or more processors, cause the one or more processors to:
receive one or more multimodal data objects associated with a subject entity and one or more interactions with an electronic device;
generate, by applying the one or more multimodal data objects to a predictive function model, a predictive function data object associated with at least the subject entity; and
perform one or more actions based on the predictive function data object.
